(19) United States
(12) Patent Application Publication
(10) Pub. No.: US 2006/0186501 A1
(43) Pub. Date: Aug. 24, 2006

(54) Semiconductor photodetector device and manufacturing method therefor

(75) Inventor: Eitaro Ishimura, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/291,936

(22) Filed: Dec. 2, 2005

(30) Foreign Application Priority Data
Feb. 24, 2005 (JP) 2005-048258

(51) Int. Cl. H01L 31/0232

(52) U.S. Cl. 257/436

(57) ABSTRACT

A laminated structure including an InGaAs light absorption layer and an InP window layer on a n-type InP substrate. A p-type diffusion layer region is formed in an InP window layer. A depletion layer between the n-type InP substrate and the p-type diffusion layer region is formed when a voltage is applied between a cathode electrode and an anode electrode. The depletion layer is thicker in at least a portion of a region under the anode electrode than in a light detecting portion. In this case, the diffusion depth of the p-type diffusion layer region may be smaller in at least the portion of the region under the anode electrode than in the light detecting portion.

### BACKGROUND OF THE INVENTION

1. Field of the Invention

The present invention relates to a semiconductor photodetector device and a manufacturing method therefor.

2. Background Art

Semiconductor photodetector devices have been used in the field of communications using optical fiber (see, e.g., Japanese Patent Laid-Open No. 2003-101061). One of such semiconductor photodetector devices is the avalanche photodiode (hereinafter referred to as “APD”). When an avalanche photodiode is irradiated with light under reverse-biased conditions, electrons are excited internally. The excited electrons excite other electrons as they move within the device. That is, the electrons initially excited by photons eventually generate a large number of electrons. These electrons may be drawn as an electric signal, allowing conversion of light to electric signals.

FIG. 13 is a cross-sectional view of a conventional avalanche photodiode (APD) for optical communications. Referring to the figure, reference numeral 101 denotes an anode electrode; 102, a p-type diffusion layer region; 103, a nonreflective film; 104, an undoped InP window layer; 105, an n-type InP electric field reduction layer; 106, an undoped InGaAsP graded layer; 107, an undoped InGaAs light absorption layer; 108, an n-type InP substrate; 109, a cathode electrode; 110, a multiplication region; 111, a guard ring region; and 112, the bonding pad portion for the anode electrode 101.

The nonreflective film 103 and the InP window layer 104 also act as a surface protective film and a multiplication layer, respectively. It should be noted that the InP window layer 104 has a large bandgap and hence does not absorb the wavelengths used in typical optical communications, such as 1.3 μm and 1.55 μm, allowing these wavelengths to pass without change. The guard ring region 111 is provided to prevent edge multiplication and is a p-type region having a low carrier concentration.

Light entering the nonreflective film 103, as shown at the top of the figure, is passed through the InP window layer 104 and then absorbed by the InGaAs light absorption layer 107, thereby generating electrons and holes. It should be noted that the APD is reverse-biased with a high voltage approximately 25 V, which depletes the InGaAs light absorption layer 107, the InGaAsP graded layer 106, the n-type InP electric field reduction layer 105, and the multiplication region 110. Therefore, the generated electrons flow toward the n-type InP substrate 108. On the other hand, the holes flow toward the multiplication region 110 having a high electric field applied thereto. The holes that have reached the multiplication region 110 causes avalanche multiplication, generating a large number of new electrons and holes. As a result, the light signal that has entered the APD is detected as a multiplied electric current signal. The magnitude of the obtained electric current signal is ten-odd times larger than when no multiplication occurs.

FIG. 14 is a cross-sectional view of a conventional APD having no guard ring region. It should be noted that in FIG. 14, components common to FIG. 13 are designated by the same reference numerals.

In this APD, a p-type diffusion region 113, corresponding to the p-type diffusion region 102 in FIG. 13, is made up of two portions having different diffusion depths so as to prevent electric field concentration around it, as shown in FIG. 14.

Incidentally, an APD must have a reduced capacitance to operate at high speed. For example, to operate an APD at 10 Gbps, it is necessary to reduce the capacitance to 0.15 pF or less. It should be noted that the capacitance of an APD is the sum of the capacitance of the depletion layer spread at the pn junction and the capacitance of the region under the bonding pad portion.

The capacitance of the depletion layer is inversely proportional to its thickness (denoted by W in FIG. 13). Therefore, the depletion layer must be formed to a large thickness to achieve a reduced capacitance. Operating the APD at high speed also requires reducing the travel time of the electrons and holes, meaning that the multiplication region 110 and the InGaAs light absorption layer 107 must be formed to a small thickness. However, this results in formation of a thin depletion layer and hence an increase in the capacitance, which prevents the APD from operating at high speed.

### SUMMARY OF THE INVENTION

The present invention has been devised in view of the above problems. It is, therefore, an object of the present invention to provide a semiconductor photodetector device with reduced depletion layer capacitance capable of operating at high speed, and a manufacturing method therefor.

According to one aspect of the present invention, a semiconductor photodetector device comprises a substrate, a laminated structure formed on the substrate which includes a semiconductor layer of a first conductive type, a light absorption layer and a window layer, an impurity region of a second conductive type formed in the window layer, a first electrode for energizing the semiconductor layer of the first conductive type, and a second electrode for energizing the impurity region of the second conductive type. A depletion layer between the semiconductor layer of the first conductive type and the impurity region of the second conductive type is formed when a voltage is applied between the first and second electrodes. The depletion layer is thicker in at least a portion of a region under the second electrode than in a region for absorbing incident light.

According to another aspect of the present invention, in a method for manufacturing a semiconductor photodetector device having a laminated structure which includes a semiconductor layer of a first conductive type, a light absorption layer, and a window layer, an impurity of a second conductive type is introduced into a predetermined region of the window layer to form a guard ring region. After forming the guard ring region, another impurity of the second conductive type is introduced into the window layer to form a shallow impurity region of the second conductive type inside the guard ring region. After forming the shallow impurity region of the second conductive type, the another impurity of the second conductive type is introduced into the window layer to form a deep impurity region of the second conductive type on the inner side of the shallow impurity region of the second conductive type.

Other objects and advantages of the present invention will become apparent from the following description.

### BRIEF DESCRIPTION OF THE DRAWINGS

FIG. 1 is a cross-sectional view of an APD according to a first embodiment.

FIG. 2 shows the light receiving portion diameter vs. capacitance of the APD according to the first embodiment.

FIGS. 3 to 6 show a method for manufacturing the APD according to the first embodiment.

FIG. 7 is a cross-sectional view of an PD according to a first embodiment.

FIG. 8 is a cross-sectional view of an APD according to a second embodiment.

FIGS. 9 and 10 are cross-sectional views of an APD according to a third embodiment.

FIG. 11 is a cross-sectional view of an APD according to a fourth embodiment.

FIG. 12 is a cross-sectional view of an APD according to a fifth embodiment.

FIG. 13 and 14 are cross-sectional views of a conventional APD.

### DETAILED DESCRIPTION OF THE PREFERRED EMBODIMENTS

A semiconductor photodetector device of the present invention comprises: a substrate; a laminated structure formed on the substrate, the laminated structure including a semiconductor layer of a first conductive type, a light absorption layer, and a window layer; an impurity region of a second conductive type formed in the window layer; a first electrode for energizing the semiconductor layer of the first conductive type; and a second electrode for energizing the impurity region of the second conductive type; wherein a depletion layer between the semiconductor layer of the first conductive type and the impurity region of the second conductive type is thicker in at least a portion of a region under the second electrode than in a region for absorbing incident light, the depletion layer being formed when a voltage is applied between the first and second electrodes. In this case, the diffusion depth of the impurity region of the second conductive type may be smaller in at least the above portion of the region under the second electrode than in the other regions. It should be noted that the semiconductor photodetector device may be either an avalanche photodiode (APD) or a photodiode (PD).

Preferred embodiments of the present invention will now be described with reference to the accompanying drawings.

### First Embodiment

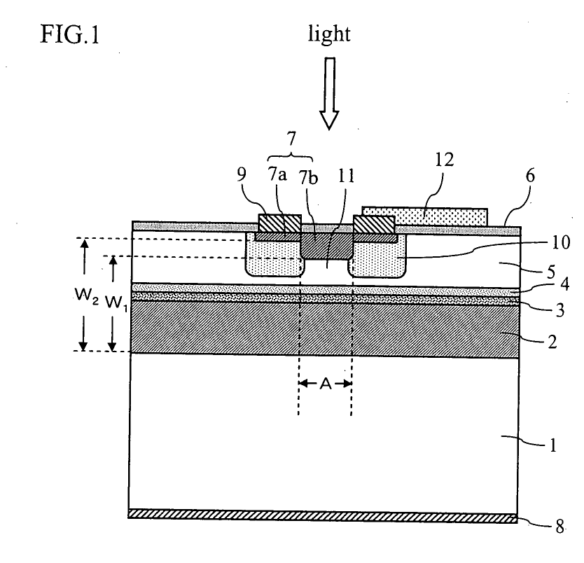

FIG. 1 is a cross-sectional view of an APD according to a first embodiment of the present invention. Referring to the figure, over an n-type InP substrate 1, also acting as a semiconductor layer of a first conductive type, are formed an undoped InGaAs light absorption layer 2, an undoped InGaAsP graded layer 3, an n-type InP electric field reduction layer 4, and an undoped InP window layer 5. Further, a nonreflective film 6, also acting as a surface protective film, is formed on the InP window layer 5. The nonreflective film 6 may be formed of, for example, an SiN film.

It should be noted that according to the present embodiment, an n-type InP layer acting as a semiconductor layer of the first conductive type may be formed on an insulative substrate, and the above undoped InGaAs light absorption layer 2, undoped InGaAsP graded layer 3, n-type InP electric field reduction layer 4, and undoped InP window layer 5 may be formed over this n-type InP layer.

Still referring to FIG. 1, a p-type diffusion layer region 7, corresponding to an impurity region of a second conductive type, is formed in the InP window layer 5. A cathode electrode 8 is a first electrode for energizing the n-type InP substrate 1, while an anode electrode 9 is a second electrode for energizing the p-type diffusion layer region 7. Further, reference numeral 10 denotes a guard ring region which is a p-type region with a low carrier concentration provided around the p-type diffusion layer region 7. Reference numeral 11 denotes a multiplication region, and 12 denotes the bonding pad portion for the anode electrode 9.

According to the present embodiment, the diffusion depth of the impurity region of the second conductive type is smaller in at least a portion of the region under the second electrode than in the region for absorbing the incident light (the light receiving portion). That is, as shown in FIG. 1, the p-type diffusion layer region 7 is made up of a shallow p-type diffusion layer region 7a formed in the region-under the anode electrode 9 and a deep p-type diffusion layer region 7b formed in a light receiving portion A.

Light entering the portion of the nonreflective film 6 not covered with the anode electrode 9, as shown at the top of the figure, is passed through the InP window-layer 5 and then absorbed by the InGaAs light absorption layer 2, thereby generating electrons and holes.

When the APD is reverse-biased, the depletion layer spreads from the shallow p-type diffusion layer region 7a and the deep p-type diffusion layer region 7b to the n-type InP substrate 1. If the thickness of the depletion layer formed in the deep p-type diffusion layer region 7b is denoted by W₁ and the thickness of the depletion layer formed in the shallow p-type diffusion layer 7a is denoted by W₂, then equation (1) below holds. As a result of the reverse bias, a high electric field is applied to the light receiving portion A, resulting in occurrence of avalanche multiplication.
W₂>W₁ (1)

Further, if the area of the light receiving portion A is denoted by S₁ and the area of the portion under the anode electrode 9 is denoted by S₂, then the pn junction capacitance Ca is expressed by equation (2) below.
Ca≈dielectric constant×{(S₁/W₁)+(S₂/W₂)} (2)

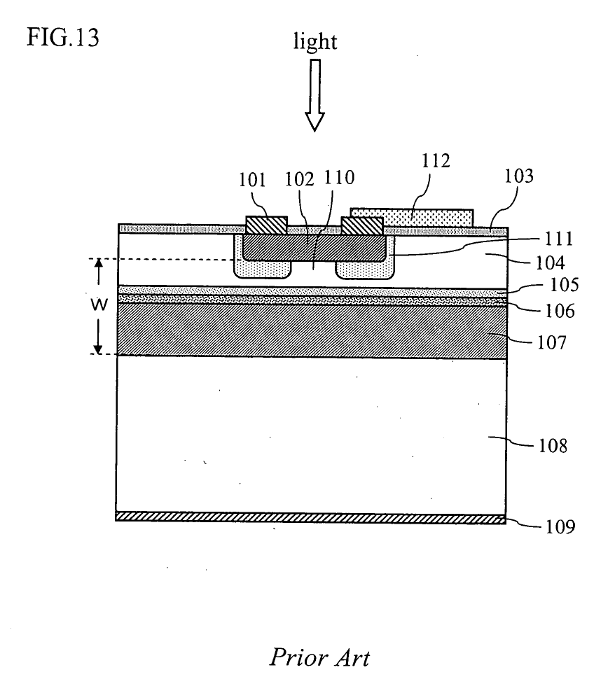

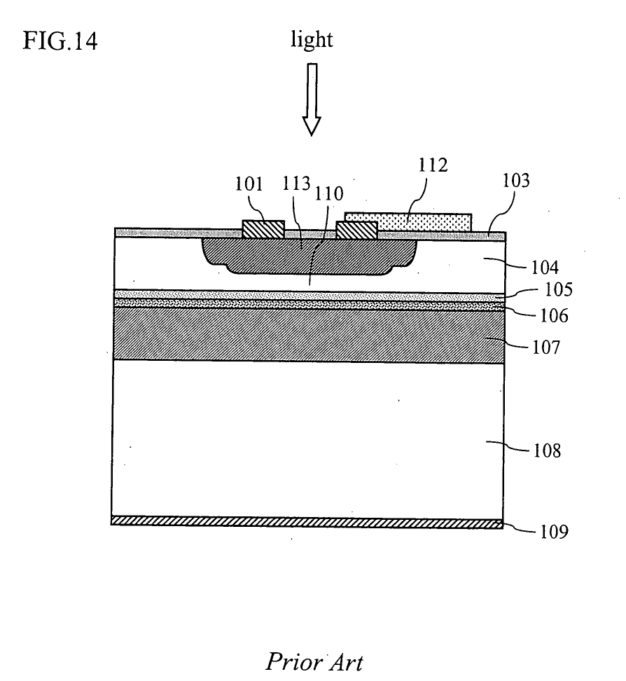

On the other hand, the pn junction capacitance Cb of the conventional example described with reference to FIG. 13 is expressed by equation (3) below.
Cb≈dielectric constant×{(S₁+S₂)/W₁} (3)

It should be noted that, strictly speaking, the light absorption layer, the graded layer, the electric field reduction layer, and the multiplication region each have a different dielectric constant. However, this specification assumes that they have the same dielectric constant, for simplicity. The above equations (2) and (3) are based on this assumption.

Equation (4) below is derived from equations (2) and (3).
Cb—Ca=dielectric constant×S₂×{(w₂−W₁}/(W₁×W₂)} (4)

Then, applying equation (1) to equation (4) results in equation (5) below.
Cb−Ca>0 Cb>Ca (5)

Equation (5) indicates that the pn junction capacitance Ca of the APD of the present embodiment is smaller than the pn junction capacitance Cb of the conventional APD.

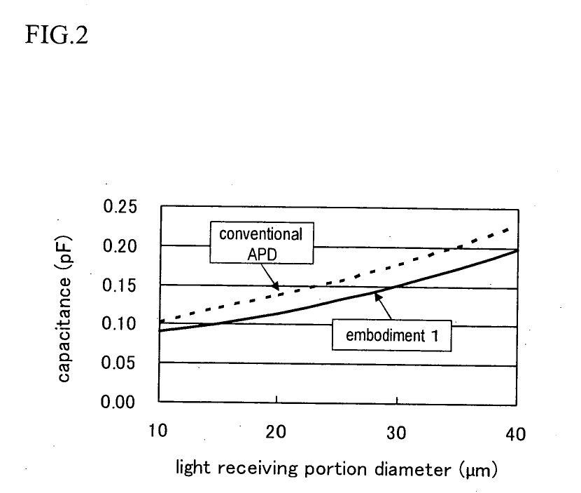

FIG. 2 compares the light receiving portion diameter vs. capacitance characteristic of an APD of the present embodiment with that of a conventional APD. FIG. 2 assumes that the capacitance of the bonding pad portion is 0.06 pF, the depletion layer thicknesses W₁ and W₂ are 2 μm and 3 μm, respectively, and the width of the anode electrode is approximately 10 μm. As can be seen from the figure, when the light receiving portion diameter is set to 20 μm (as in APDs used in 10 Gbps communications), the present embodiment has a capacitance 16% smaller than that of the conventional example, for example.

Thus, the present embodiment can reduce the capacitance of the depletion layer spread at the pn junction of an APD, as compared to conventional arrangements, allowing the APD to operate at high speed.

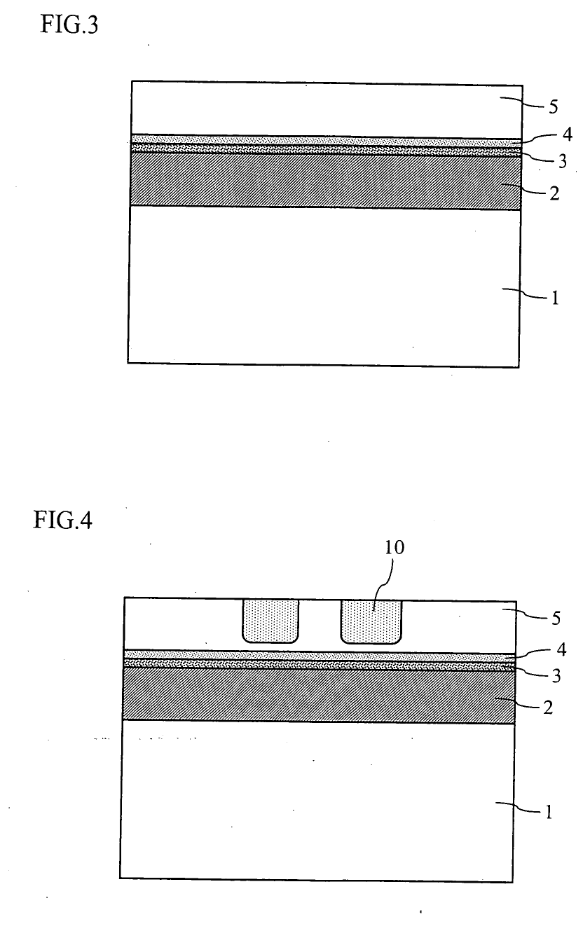

There will now be described a method for manufacturing an APD according to the present embodiment with reference to FIGS. 3 to 6. It should be noted that in these figures, components common to FIG. 1 are designated by the same reference numerals.

First of all, the undoped InGaAs light absorption layer 2, the undoped InGaAsP graded layer 3, the n-type InP electric field reduction layer 4, and the undoped InP window layer 5 are formed over the n-type InP substrate 1 in that order, as shown in FIG. 3.

Then, after introducing p-type impurities such as Be (beryllium) into a predetermined region of the InP window layer 5, activation annealing is carried out to form the guard ring region 10, as shown in FIG. 4.

Then, p-type impurities such as Zn (zinc) are introduced into the InP window layer 5 to form the shallow p-type diffusion layer region 7a inside the guard ring region 10, as shown in FIG. 5.

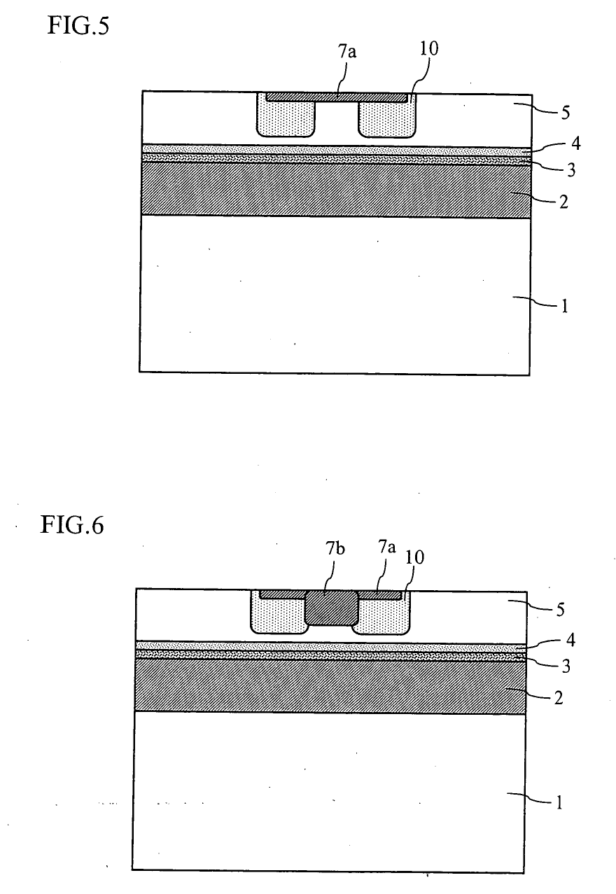

After that, p-type impurities such as Zn (zinc) are further introduced into the InP window layer 5 to form the deep p-type diffusion layer region 7b on the inner side of the shallow p-type diffusion layer region 7a, as shown in FIG. 6.

Thus, the guard ring region 10 is formed before forming the shallow p-type diffusion layer region 7a and the deep p-type diffusion layer region 7b, for the following reason. The temperature of the annealing performed to form the guard ring region 10 is higher than the temperatures at which the shallow p-type diffusion layer region 7a and the deep p-type diffusion layer region 7b are formed. Therefore, if the guard ring region 10 is formed after forming these diffusion layers, the p-type impurities will diffuse to a deep position, resulting in an inability to form the shallow p-type diffusion layer region 7a and the deep p-type diffusion layer region 7b at desired positions.

Further, the deep p-type diffusion layer region 7b is formed after forming the shallow p-type diffusion layer region 7a, for the following reason. The thickness of the multiplication layer 11 shown in FIG. 1 is defined by the depth, or thickness, of the deep p-type diffusion layer region 7b. Therefore, the margin for forming the deep p-type diffusion layer region 7b is smaller than that for forming the shallow p-type diffusion layer region 7a. If the deep p-type diffusion layer region 7b is formed before forming the shallow p-type diffusion layer region 7a, the diffusion of impurities to form the shallow p-type diffusion layer region 7a results in further diffusion of impurities into the deep p-type diffusion layer region 7b, making it difficult to form the multiplication region 11 to an appropriate thickness.

After forming the deep p-type diffusion layer region 7b, as described above, the nonreflective film 6 is formed on the InP window layer 5, and furthermore the anode electrode 9 and the bonding pad portion 12 for the anode electrode 9 are formed in predetermined regions. Lastly, the cathode electrode 8 is formed on the back surface of the n-type InP substrate 1, producing the structure shown in FIG. 1.

Thus, the above method of the present invention for manufacturing an APD forms impurity regions of a second conductive type having different diffusion depths and further forms a guard ring around these impurity regions of the second conductive type.

It should be noted that even though the present embodiment is descried as applied to an APD, a type of semiconductor photodetector device, with reference to FIG. 1, the present invention can also be applied to a photodiode (PD), another type of semiconductor photodetector device.

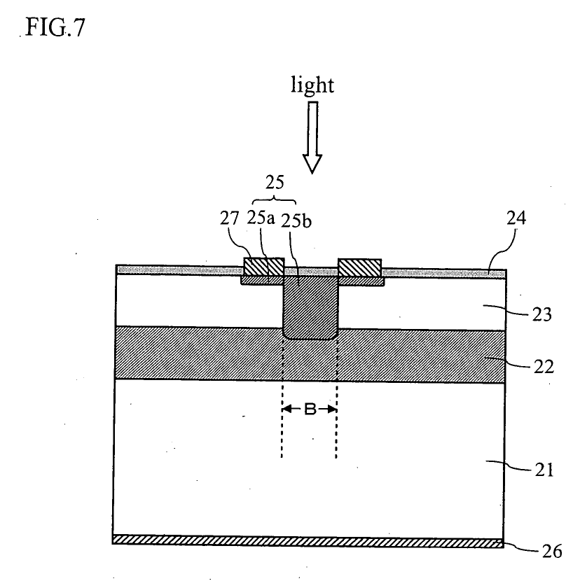

FIG. 7 is a cross-sectional view of a PD according to the present embodiment. Referring to the figure, an undoped InGaAs light absorption layer 22 and an undoped InP window layer 23 are formed on an n-type InP substrate 21, also acting as a semiconductor layer of a first conductive type. Further, a nonreflective film 24, also acting a surface protective film, is formed on the InP window layer 23. The nonreflective film 24 may be formed of, for example, an SiN film. It should be noted that an n-type InP layer acting as a semiconductor layer of the first conductive type may be formed on an insulative substrate, and the above undoped InGaAs light absorption layer 22 and undoped InP window layer 23 may be formed over this n-type InP layer.

Still referring to FIG. 7, a p-type diffusion layer region 25, corresponding to an impurity region of a second conductive type, is formed in the InP window layer 23. A cathode electrode 26 is a first electrode for energizing the n-type InP substrate 21, while an anode electrode 27 is a second electrode for energizing the p-type diffusion layer region 25.

As shown in FIG. 7, the p-type diffusion layer region 25 is made up of a shallow p-type diffusion layer region 25a formed in the region under the anode electrode 27 and a deep p-type diffusion layer region 25b formed in a light receiving portion B. It should be noted that the deep p-type diffusion layer region 25b reaches the InGaAs light absorption layer 22. That is, the diffusion depth of the impurity region of the second conductive type is smaller in at least a portion of the region under the second electrode than in the region for absorbing the incident light (the light receiving portion B), and furthermore the portion of the impurity region of a second conductive type formed in the region for absorbing the incident light (the light receiving portion B) reaches the light absorption layer. This structure reduces the capacitance of the depletion layer spread at the pn junction of the PD, as compared to conventional arrangements, allowing the PD to operate at high speed.

### Second Embodiment

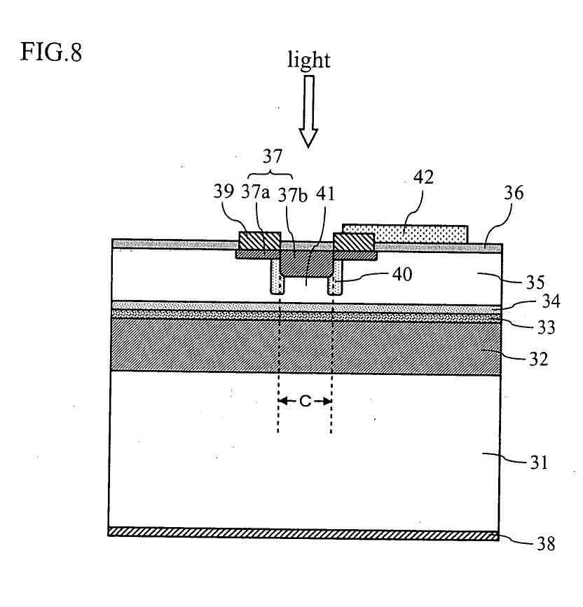

FIG. 8 is a cross-sectional view of an APD according to a second embodiment of the present invention. Referring to the figure, over an n-type InP substrate 31, also acting as a semiconductor layer of a first conductive type, are formed an undoped InGaAs light absorption layer 32, an undoped InGaAsP graded layer 33, an n-type InP electric field reduction layer 34, and an undoped InP window layer 35. Further, a nonreflective film 36, also acting as a surface protective film, is formed on the InP window layer 35. The nonreflective film 36 may be formed of, for example, an SiN film.

It should be noted that according to the present embodiment, an n-type InP layer acting as a semiconductor layer of the first conductive type may be formed on an insulative substrate, and the above undoped InGaAs light absorption layer 32, undoped InGaAsP graded layer 33, n-type InP electric field reduction layer 34, and undoped InP window layer 35 may be formed over this n-type InP layer.

Still referring to FIG. 8, a p-type diffusion layer region 37, corresponding to an impurity region of a second conductive type, is formed in the InP layer 35. A cathode electrode 38 is a first electrode for energizing the n-type InP substrate 31, while an anode electrode 39 is a second electrode for energizing the p-type diffusion layer region 37. Further, reference numeral 40 denotes a guard ring region which is a p-type region with a low carrier concentration provided around the p-type diffusion layer region 37. Reference numeral 41 denotes a multiplication region, and 42 denotes the bonding pad portion for the anode electrode 39.

The present embodiment is similar to the first embodiment in that the p-type diffusion layer region 37 is made up of a shallow p-type diffusion layer region 37a formed in the region under the anode electrode 39 and a deep p-type diffusion layer region 37b formed in a light receiving portion C. However, the present embodiment differs from the first embodiment in that the guard ring region 40 is formed only around the deep p-type diffusion layer region 37b. That is, the present embodiment is characterized in that the guard ring is provided only around the portion of the impurity region of the second conductive type formed in the region for absorbing the incident light (the light receiving portion C). The reason for employing such a structure is that the shallow p-type diffusion layer region 37a has a high breakdown voltage since the depletion layer formed under the shallow p-type diffusion layer region 37a has a large thickness.

Generally, a guard ring region becomes a source of a dark current. However, since the present embodiment forms the guard ring region 40 only around the deep p-type diffusion layer region 37b, the area of the guard ring region can be reduced to reduce the dark current.

### Third Embodiment

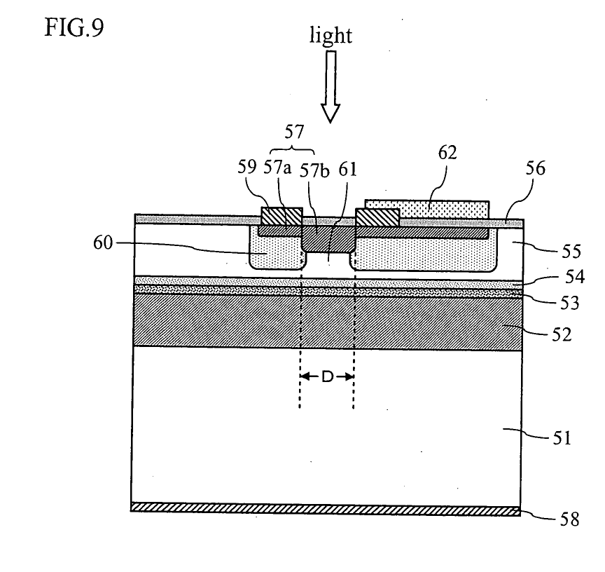

FIG. 9 is a cross-sectional view of an APD according to a third embodiment of the present invention. Referring to the figure, over an n-type InP substrate 51, also acting as a semiconductor layer of a first conductive type, are formed an undoped InGaAs light absorption layer 52, an undoped InGaAsP graded layer 53, an n-type InP electric field reduction layer 54, and an undoped InP window layer 55. Further, a nonreflective film 56, also acting as a surface protective film, is formed on the InP window layer 55. The nonreflective film 56 may be formed of, for example, an SiN film.

It should be noted that according to the present embodiment, an n-type InP layer acting as a semiconductor layer of the first conductive type may be formed on an insulative substrate, and the above undoped InGaAs light absorption layer 52, undoped InGaAsP graded layer 53, n-type InP electric field reduction layer 54, and undoped InP window layer 55 may be formed over this n-type InP layer.

Still referring to FIG. 9, a p-type diffusion layer region 57, corresponding to an impurity region of a second conductive type, is formed in the InP window layer 55. A cathode electrode 58 is a first electrode for energizing the n-type InP substrate 51, while an anode electrode 59 is a second electrode for energizing the p-type diffusion layer region 57. Further, reference numeral 60 denotes a guard ring region which is a p-type region with a low carrier concentration provided around the p-type diffusion layer region 57. Reference numeral 61 denotes a multiplication region, and 62 denotes the bonding pad portion for the anode electrode 59.

The present embodiment is similar to the first embodiment in that the p-type diffusion layer region 57 is made up of a shallow p-type diffusion layer region 57a formed in the region under the anode electrode 59 and a deep p-type diffusion layer region 57b formed in a light receiving portion D. However, the present embodiment differs from the first embodiment in that the guard ring region 60 and the shallow p-type diffusion layer region 57a are also formed in the region under the bonding pad portion 62.

The bonding pad portion 62 and the region under it form an MIS (Metal Insulator Semiconductor) structure. Therefore, the capacitance of the region under the bonding pad portion 62 is determined by the thickness and the dielectric constant of the nonreflective film 56. It should be noted that generally the thickness of the nonreflective film 56 is thin (e.g., approximately 0.18 μm). Therefore, generally, the capacitance of the region under the bonding pad portion 62 per unit area is larger than that of the pn junction portion.

According to the present embodiment, however, a pn junction is formed in the region under the bonding pad portion 62 as a result of forming the guard ring region 60 and the shallow p-type diffusion layer region 57a in the this region. This allows the capacitance of the region under the bonding pad portion 62 to be reduced.

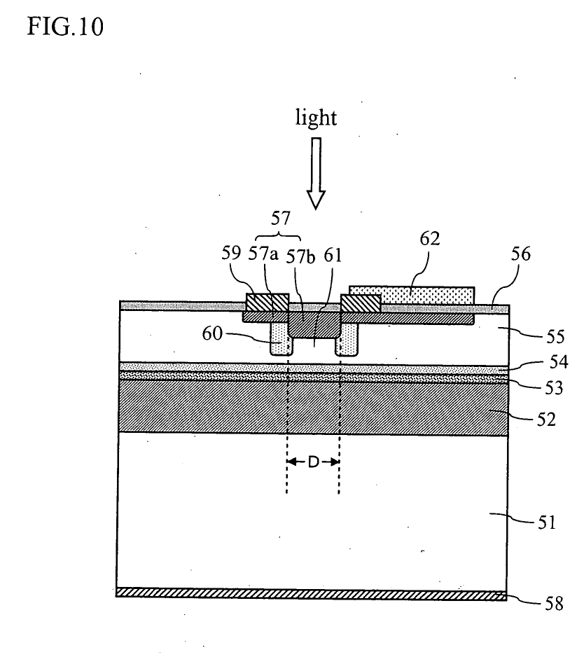

It should be noted that even though in FIG. 9 the guard ring region 60 is formed throughout the region under the bonding pad portion 62, the present invention is not limited to this particular arrangement. According to the present invention, the guard ring region 60 may be formed only around the deep p-type diffusion layer region 57b, as shown in FIG. 10. That is, the guard ring may be formed only around the portion of the impurity region of the second conductive type formed in the region for absorbing the incident light (the light receiving portion D). This allows for reduction of the dark current, as well as producing the above effect.

### Fourth Embodiment

According to a fourth embodiment of the present invention, a multiplication layer made up of an AlInAs layer and an electric field reduction layer are formed between a semiconductor layer of a first conductive type and a light absorption layer in that order.

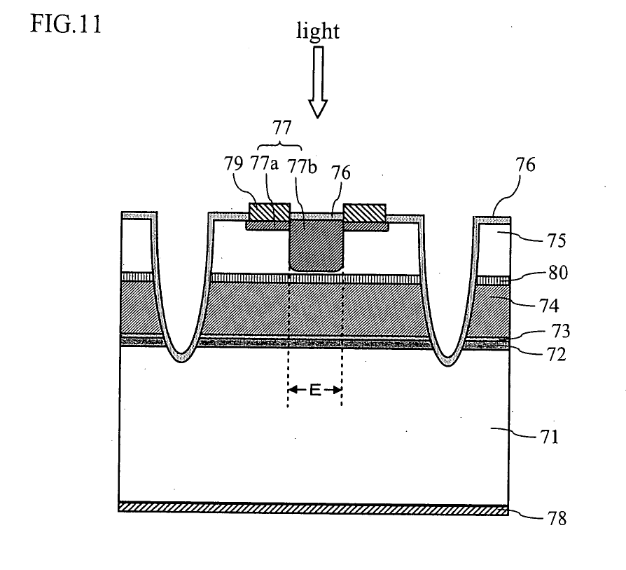

FIG. 11 is a cross-sectional view of an-APD according to the present embodiment. Referring to the figure, over an n-type InP substrate 71, also acting as the semiconductor layer of the first conductive type, are formed an AlInAs multiplication layer 72, a p-type InP electric field reduction layer 73, an undoped InGaAs light absorption layer 74, an undoped InGaAsP graded layer 80, and an undoped InP window layer 75. Further, a nonreflective film 76, also acting as a surface protective film, is formed on the InP window layer 75. The nonreflective film 76 may be formed of, for example, an SiN film.

It should be noted that according to the present embodiment, an n-type InP layer acting as the semiconductor layer of the first conductive type may be formed on an insulative substrate, and the above AlInAs multiplication layer 72, p-type InP electric field reduction layer 73, undoped InGaAs light absorption layer 74, undoped InGaAsP graded layer 80, and undoped InP window layer 75 may be formed over this n-type InP layer.

Still referring to FIG. 11, a p-type diffusion layer region 77, corresponding to an impurity region of a second conductive type, is formed in the InP window layer 75. A cathode electrode 78 is a first electrode for energizing the n-type InP substrate 71, while an anode electrode 79 is a second electrode for energizing the p-type diffusion layer region 77.

According to the present embodiment, the diffusion depth of the impurity region of the second conductive type is smaller in at least a portion of the region under the second electrode than in the other regions. That is, as shown in FIG. 11, the p-type diffusion layer region 77 is made up of a shallow p-type diffusion layer region 77a formed under the anode electrode 79 and a deep p-type diffusion layer region 77b formed in a light receiving portion E. This structure reduces the capacitance of the depletion layer spread at the pn junction of the APD, as compared to conventional arrangements, allowing the APD to operate at high speed.

It should be noted that in the APD shown in FIG. 11, the AlInAs multiplication layer 72 and the p-type InP electric field reduction layer 73 are provided under the InGaAs light absorption layer 74 so as to inject electrons into the AlInAs multiplication layer 72. Therefore, according to the present embodiment, since the AlInAs multiplication layer 72, at which electric field concentration occurs, is not in contact with the p-type diffusion layer region 77, a guard ring need not be provided around the p-type diffusion layer region 77.

### Fifth Embodiment

According to a fifth embodiment of the present invention, a first electrode is formed on a predetermined region of the back surface of a substrate, and a second electrode is formed on an impurity region of a second conductive type. Furthermore, light enters the portion of the back surface of the substrate not covered with the first electrode.

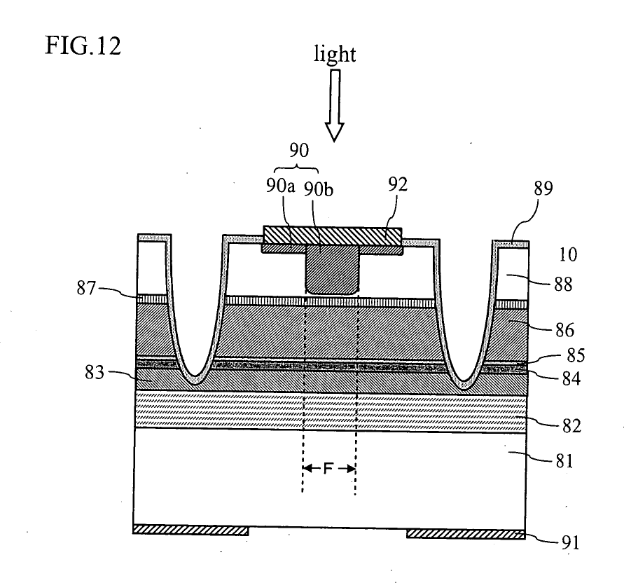

FIG. 12 is a cross-sectional view of an APD according to the present embodiment. Referring to the figure, over an n-type InP substrate 81, also acting as a semiconductor layer of a first conductive type, are formed an n-type buffer layer 82, an n-type semiconductor layer 83, a multiplication layer 84, a p- type InP electric field reduction layer 85, an undoped InGaAs light absorption layer 86, an undoped InGaAsP graded layer 87, and an undoped InP window layer 88. Further, a nonreflective film 89, also acting as a surface protective film, is formed on the InP window layer 88. The nonreflective film 89 may be formed of, for example, an SiN film.

It should be noted that according to the present embodiment, an n-type InP layer acting as a semiconductor layer of the first conductive type may be formed on an insulative substrate, and the above n-type buffer layer 82, n-type semiconductor layer 83, multiplication layer 84, p-type InP electric field reduction layer 85, undoped InGaAs light absorption layer 86, undoped InGaAsP grated layer 87, and undoped InP window layer 88 may be formed over this n-type InP layer.

Still referring to FIG. 12, a p-type diffusion layer region 90, corresponding to the impurity region of the second conductive type, is formed in the InP window layer 88. A cathode electrode 91 is the first electrode formed on a predetermined region of the back surface of the n-type InP substrate 81 and used to energize the n-type InP substrate 81. An anode electrode 92 is the second electrode formed on the p-type diffusion layer region 90 and used to energize the p-type diffusion layer region 90.

Light entering the portion of the back surface of the n-type InP substrate 81 not covered with the cathode electrode 91, as shown at the bottom of the figure, is absorbed by a light receiving portion F, thereby generating electrons and holes.

According to the present embodiment, the diffusion depth of the impurity region of the second conductive type is smaller in at least a portion of the region under the second electrode than in the region for absorbing the incident light (the light receiving portion F). That is, as shown in FIG. 12, the p-type diffusion layer region 90 is made up of a shallow p-type diffusion layer region 90a formed under the anode electrode 92 and a deep p-type diffusion layer region 90b formed in the light receiving portion F. This structure reduces the capacitance of the depletion layer spread at the pn junction of the APD, as compared to conventional arrangements, allowing the APD to operate at high speed.

It should be noted that the present invention is not limited to the embodiments described above, and various alterations may be made thereto without departing from the spirit and scope of the invention.

The features and advantages of the present invention may be summarized as follows.

The first aspect of the present invention allows a semiconductor photodetector device to be configured such that the depletion layer spread at the pn junction has a reduced capacitance, as compared to conventional arrangements, enabling the device to operate at high speed.

The second aspect of the present invention provides a semiconductor photodetector device configured such that impurity regions of a second conductive type having different diffusion depths are formed therein and a guard ring is provided around these impurity regions.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2005-048258, filed on Feb. 24, 2005 including specification, claims, drawings and summary, on which the Convention priority of the present application is based, are incorporated herein by reference in its entirety.

1. A semiconductor photodetector device comprising:
a substrate;
a laminated structure on said substrate, said laminated structure including a semiconductor layer of a first conductivity type, a light absorption layer, and a window layer;
an impurity region of a second conductivity type in said window layer;
a first electrode for energizing said semiconductor layer of the first conductivity type; and
a second electrode for energizing said impurity region of said the second conductivity type, wherein a depletion layer between said semiconductor layer of the first conductivity type and said impurity region of the second conductivity type is thicker in at least a portion of a region under said second electrode than in a region for absorbing incident light, the depletion layer being formed when a voltage is applied between said first and second electrodes.

2. The semiconductor photodetector device according to claim 1, wherein the depth of said impurity region of the second conductivity type is smaller in at least said portion of said region under said second electrode than in said region for absorbing the incident light.

3. The semiconductor photodetector device according to claim 1, further comprising a bonding pad portion for said second electrode, wherein said impurity region of the second conductivity type is also in a region under said bonding pad portion.

4. The semiconductor photodetector device according to claim 1, including a guard ring around said impurity region of the second conductivity type.

5. The semiconductor photodetector device according to claim 4, wherein said guard ring is only around the portion of said impurity region of the second conductivity type located in said region for absorbing the incident light.

6. The semiconductor photodetector device according to claim 1, further comprising a multiplication layer and an electric field reduction layer between said semiconductor layer of the first conductivity type and said light absorption layer in that order, wherein said multiplication layer includes an AlInAs layer.

7. The semiconductor photodetector device according to claim 1, wherein:
said first electrode is on a predetermined region of a back surface of said substrate; and
the incident light enters the portion of said back surface of said substrate not covered by said first electrode.

8. A method for manufacturing a semiconductor photodetector device having a laminated structure which includes a semiconductor layer of a first conductivity type, a light absorption layer, and a window layer, said method comprising
introducing an impurity producing a second conductivity type into a predetermined region of said window layer to form a guard ring region;
after forming said guard ring region, introducing another impurity producing the second conductivity type into said window layer to form a shallow impurity region of the second conductivity type inside said guard ring region; and
after forming said shallow impurity region of the second conductivity type, further introducing another impurity producing the second conductivity type into said window layer to form a deep impurity region of the second conductivity type on the inner side of said shallow impurity region of said second conductivity type.
